(19) United States
(12) Patent Application Publication
(10) Pub. No.: US 2014/0380115 A1
(43) Pub. Date: Dec. 25, 2014

(54) ERROR DETECTING AND CORRECTING STRUCTURED LIGHT PATTERNS

(71) Applicant: David D. Bar-On, Givat Ella (IL)

(72) Inventor: David D. Bar-On, Givat Ella (IL)

(21) Appl. No.: 14/127,458

(22) PCT Filed: Jun. 24, 2013
(86) PCT No.: PCT/US2013/047371

§ 371 Date: Dec. 18, 2013

(51) Int. Cl. H03M 13/29; H04B 10/80; H04L 1/00

(52) U.S. Cl. CPC H03M 13/2915; H04L 1/0061; H04B 10/80
USPC 714/758

(57) ABSTRACT

Techniques are disclosed for detecting image depth in three-dimensional (3-D) surface imaging. The disclosed techniques can be used, for example, to provide structured light encoded with a coded word that includes error-correcting code (ECC). The ECC is effectively configured to detect and correct data errors as may result, for example, from the presence of ambient light and/or camera-noise-causing errors during imaging. In an example case, the coded word is a 15-bit pattern provided in a 3×5 matrix and including: (1) nine data bits of disparity code; (2) five ECC bits for correcting an error and detecting two errors; and (3) one 8-bit/10-bit encoding bit to ensure the presence of a transient pixel in the data for white threshold level detection. Greater or lesser bit quantities and varied bit partitioning matrices can be provided, as desired. In some cases, imaging robustness and/or power usage can be improved using the disclosed techniques.

### BACKGROUND

Three-dimensional (3-D) surface imaging involves a number of non-trivial challenges and has faced particular complications with respect to acquiring depth information pertaining to objects being imaged.

### BRIEF DESCRIPTION OF THE DRAWINGS

FIG. 1 illustrates a three-dimensional (3-D) imaging system configured in accordance with an embodiment of the present disclosure.

FIG. 2 illustrates an example use of the system of FIG. 1, in accordance with an embodiment of the present disclosure.

FIG. 3 illustrates an example 15-bit coded word arranged in a 3×5 matrix, in accordance with an embodiment of the present disclosure.

FIGS. 3′ and 3″ illustrate a 4×4 matrix and a 5<5 matrix, respectively, which can be used for bit partitioning, in accordance with some embodiments of the present disclosure.

FIG. 4 is a flow diagram illustrating a process for generating a coded word for patterning a mask for use in generating structured light, in accordance with an embodiment of the present disclosure.

FIG. 5 demonstrates the alignment of an example coded transmitter word with respect to an example receiver matrix, in accordance with an embodiment of the present disclosure.

FIG. 6A is a block diagram of a receiver configured in accordance with au embodiment of the present disclosure.

FIG. 6B illustrates a FIFO module configured in accordance with an embodiment of the present disclosure.

FIGS. 7A and 7B represent operation of a minimum-maximum level detection module, in accordance with an embodiment of the present disclosure.

FIG. 8 is a block diagram of a light source power control module configured in accordance with an embodiment of the present disclosure.

FIGS. 9A through 9D illustrate four example cases of misaligned transmit and receive patterns.

FIG. 10 represents an example implementation of a sub-pixel alignment mechanism, in accordance with an embodiment of the present disclosure.

FIG. 11 illustrates a plurality of masks for use in generating temporal structured light, in accordance with an embodiment of the present disclosure.

FIG. 12 illustrates an example system that may carry out the techniques for providing structured light encoded with a coded word including error-correcting code (ECC) to detect and correct errors as described herein, in accordance with some embodiments.

FIG. 13 illustrates embodiments of a small form factor device in which the system of FIG. 12 may be embodied.

### DETAILED DESCRIPTION

Techniques are disclosed for detecting image depth in three-dimensional (3-D) surface imaging. The disclosed techniques can be used, for example, to provide structured light encoded with a coded word that includes error-correcting code (ECC). The ECC is effectively configured to detect and correct data errors as may result, for example, from the presence of ambient light and/or camera-noise-causing errors during imaging. In an example case, the coded word can be a 15-bit pattern provided in a 3×5 matrix and including: (1) nine data bits of disparity code; (2) five ECC bits for correcting an error and detecting two errors; and (3) one 8-bit/10-bit encoding bit to help ensure the presence of a transient pixel in the data for white threshold level detection. Greater or lesser bit quantities and varied bit partitioning matrices can be provided, as desired. In some cases, imaging robustness can be improved using the disclosed techniques. Also, in some instances, the quantity of errors detected can be used, for example, to tune the output power of the light source utilized during imaging, in some cases reducing the output power until a desired error threshold is reached. Numerous configurations and variations will be apparent in light of this disclosure.

General Overview

As previously indicated, there are a number of non-trivial issues that can arise which can complicate three-dimensional (3-D) surface imaging. For instance, one non-trivial issue pertains to the ability to acquire depth information pertaining to an object. To do so, 3-D cameras can employ structured light and coded light. However, in the case of a structured light process, it is difficult to efficiently encode the disparity code in the patterns of the static projected slide utilized in such a process. Also, existing structured light systems utilize very large slide patterns, which result in poor resolution a id are not immune to noise and thus require use of very high powered lasers and provision of a dark environment. Furthermore, existing structured light systems have issues with undetected, noisy, and/or faulty pixels and suffer from depth-reading errors. Increasing the power of the laser or the size of the patterns in an attempt to mitigate these complications negatively impacts the resolution. Also, using a coded light process which uses time multiplexing to encode the pattern in a small space in an attempt to regain this lost resolution increases system complexity and is poorly suited for detecting moving objects. In any case, these existing systems are very complicated to calibrate, and most algorithms employed in these approaches require running a calibration process before using the system.

Thus, and in accordance with an embodiment of the present disclosure, techniques are disclosed for providing structured light encoded with a coded word including error-correcting code (ECC) and which is capable of detecting and correcting errors. In some embodiments, the structured light can be encoded, for example, with a 15-bit pattern provided in a 3×5 matrix including: (1) nine data bits; (2) five ECC bits; and (3) one 8-bit/10-bit encoding bit. In some such cases, the nine data bits can be a disparity code, the five ECC bits can be used to correct an error and to detect two errors, and the 8-bit/10-bit encoding bit can help to ensure the presence of a transient pixel in the data for white threshold level detection. Greater or lesser bit quantities and varied matrices (e.g., 4×4; 4×5; 5×5; etc.) can be provided, as desired, in accordance with other embodiments. It may be desirable in some cases to provide additional ECC bits for matrices larger than 3×5, for example, for additional robustness.

The techniques disclosed herein can be used, for example, for sub-pixel position calculations, automatic brightness calibration, and/or pixel alignment, in accordance with some embodiments. Furthermore, and in accordance with an embodiment, the use of ECC in the structured light can be utilized, for example, for managing the output power of the light source (e.g., a laser) which emits the light to be encoded with a coded word. That is, in some cases, the output power can be minimized or otherwise reduced, for example, to conserve power, by decreasing the output power of the light source until the errors are no longer correctable. Thus, in this sense, the quantity of errors detected can be used, for example, to tune the output power of the light source utilized during imaging, in some cases reducing the output power until a desired error threshold is reached.

Some embodiments can be used, for example, with 3-D imaging devices (e.g., cameras, video cameras, etc.), which, in some cases, may be utilized in any of a wide variety of computing devices, such as: a laptop/notebook computer; a tablet computer; a mobile phone or smartphone; a personal digital assistant (PDA); a cellular handset; a handheld gaming device; a gaming platform; a desktop computer; a smart television; and/or a videoconferencing system. Some embodiments can be used, for example, in: (1) 3-D vision applications, such as machine vision (MV) and other imaging-based automatic inspection and analysis; (2) depth cameras; (3) gesture recognition; and/or (4) gaming. Numerous suitable uses and applications will be apparent in light of this disclosure.

Some embodiments may realize advantages or benefits, for example, as compared to existing approaches. For instance, some embodiments may exhibit increased resistance to degradation of performance, for example, as otherwise might result from a noisy/hostile environment. Some embodiments may realize an increase in the quality of the depth of picture of a 3-D camera. Some embodiments may realize a reduction in power, for example, as compared to existing designs and may be implemented to reduce the power requirements of a host 3-D camera, which in turn may allow such a 3-D camera to be used in smaller or otherwise more power-sensitive platforms (e.g., smaller mobile computing devices). Some embodiments may realize a reduction in cost, for example, as compared to existing designs (e.g., such as by permitting use of optical sensors with less than optimal pixel performance or with a greater quantity of defective pixels). Also, and in accordance with an embodiment, use of the disclosed techniques may be detected, for example, by testing if a small spot of light (e.g., noise) is causing errors in the depth map or if it is robust to noise. As will be further appreciated, various embodiments can be implemented, for example, in software, firmware, hardware, and/or combination thereof.

Methodology and Operation

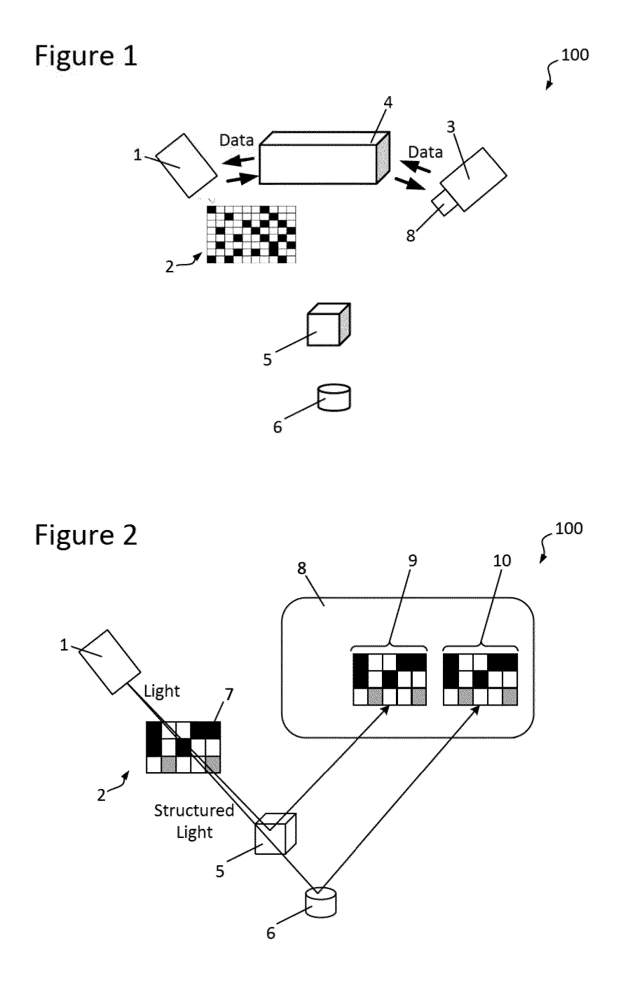

FIG. 1 illustrates a three-dimensional (3-D) imaging system 100 configured in accordance with an embodiment of the present disclosure, and FIG. 2 illustrates an example use of that system 100. As can be seen, system 100 includes a light source 1, which can be a projector or any other light source suitable for use in 3-D surface imaging, as will be apparent in light of this disclosure. The light emitted by light source 1 can be passed through a coded pattern mask 2 to produce structured light, which in turn can be used to provide structured-light illumination of a scene within the field of illumination of light source 1. In accordance with some embodiments, mask 2 can be patterned with a code, such as coded word 7 (discussed below), for use in 3-D surface imaging. In some instances, mask 2 may be engraved with coded word 7 (e.g., mask 2 may be provided with a static pattern which represents coded word 7). In any case, the patterned mask 2 (e.g., patterned with coded word 7) can be reflected to an imaging screen 8 of an imaging input device 3. Imaging input device 3 can be, for example, a still camera, a video camera, or any other imaging device suitable for use in 3-D surface imaging, as will be apparent in light of this disclosure. In some cases, imaging input device 3 may include components such as, but not limited to, an optics assembly, an image sensor, and an image/video encoder. However, the present disclosure is not so limited, as in some other cases, imaging input device 3 may be only an imaging sensor/optics (e.g., it need not be an entire camera/video camera). Numerous suitable configurations will be apparent in light of this disclosure.

As can further be seen, system 100 can include a processing unit 4. In some embodiments, processing unit 4 can be separate from other components of system 100, while in some other embodiments, processing unit 4 can be incorporated into or otherwise integrated with another portion of system 100 (e.g., with imaging input device 3, with light source 1, etc.). In any case, processing unit 4 can be configured to receive data from and/or transmit data to one or more other portions of system 100 or portions external to system 100. To that end, and in accordance with some embodiments, processing unit 4 can be configured for wired (e.g., Universal Serial Bus or USB; Ethernet; FireWire; mobile industry processor interface, or MIPI; etc.) and/or wireless (e.g., Wi-Fi®; Bluetooth®; etc.) communications, for example, with light source 1 and/or imaging input device 3. As such, it may be desirable to ensure that light source 1 and/or imaging input device 3 also are suitably configured for the desired type(s) of communications with processing unit 4.

As will be appreciated, the reflected position of mask 2 (e.g., patterned with coded word 7) as detected by imaging input device 3 at imaging screen 8 is based on triangulation. If the structured light (e.g., as provided by light source 1 in conjunction with coded word 7) is incident with a non-planar surface of an object within the field of illumination of light source 1, the geometric shape of that surface serves to distort the projected structured-light pattern as observed by imaging input device 3. This distortion conveys information about the incident surface, which in turn can be used, in accordance with an embodiment, to determine the 3-D surface shape of the object in the scene. If the structured-light pattern is returned from an object which is near (e.g., near-field object 5) or far (e.g., far-field object 6), then it is detected by imaging input device in different locations 9 and 10, respectively, on imaging screen 8. Using known triangulation techniques, the distance can be calculated by the amount of shift (disparity) of the reflected pattern from the expected position to the actual position.

Thus, and in accordance with an embodiment, processing unit 4 can be configured to process such information as gathered by imaging input device 3, for example, to extract the 3-D surface shape of a given object (e.g., near-field object 5; far-field object 6) within the field of illumination of light source 1 and mask 2 (e.g., which may be patterned with coded word 7, discussed below). Processing unit 4 also may be configured to output the processed data for downstream use (e.g., by a portion external to system 100).

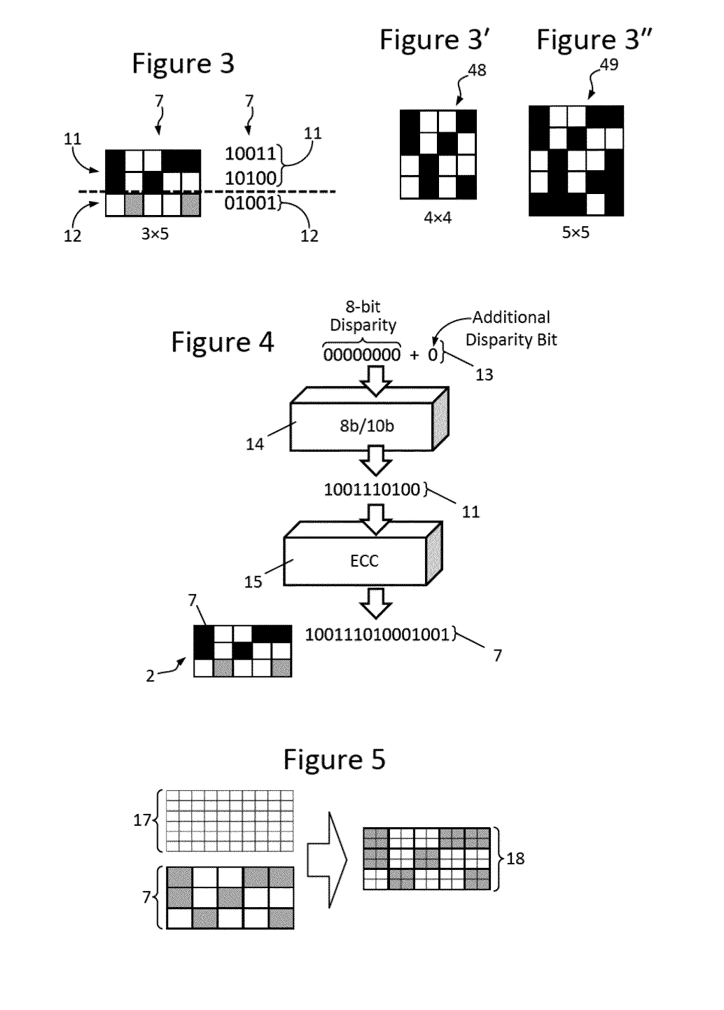

As previously noted, and in accordance with some embodiments, mask 2 can be patterned with a coded word 7 to provide structured-light illumination of a scene within the field of illumination of light source 1. FIG. 3 illustrates an example 15-bit coded word 7 arranged in a 3×5 matrix, in accordance with an embodiment of the present disclosure. As can be seen, coded word 7 is made up of three rows with five bits each. In accordance with an embodiment, the first ten bits of coded word 7 are an 8-bit/10-bit representation of the 8-bit disparity, that is, the 8-bit binary word ‘00000000’ is converted to the 10-bit binary word 11 ‘1001110100.’ Furthermore, and in accordance with an embodiment, the last five bits 12 of the coded word 7 represent five bits of error-correcting code (ECC), which, in some example cases, can be one of the Hamming codes. In any case, the first ten bits 11 may not be ‘00000’ or ‘11111,’ as will be appreciated. Thus, the ECC bits 12 may have at least one transition and therefore do not require an additional 4-bit/5-bit encoding, in accordance with an embodiment.

As will be farther appreciated, the 8-bit/10-bit encoding scheme has two 10-bit representations for every 8-bit word, which are termed the positive running disparity (RD+) and negative running disparity (RD−) and which can be used, for example, in data communications for DC balancing of a long data stream. The techniques disclosed herein can be used, in accordance with some embodiments, to encode an additional disparity bit in the RD+/RD− for a total of nine disparity bits such as can be seen with respect to disparity code 13, discussed below with reference to FIG. 4).

As previously noted, the present disclosure is not limited to only a coded word 7 arranged in a 3×5 matrix. For example, consider FIGS. 3′ and 3″, which illustrate a 4×4 matrix 48 and a 5×5 matrix 49, respectively, which can be used for bit partitioning, in accordance with some embodiments of the present disclosure. As will be appreciated in light of this disclosure, the greater the number of bits used for the coded word 7 used to pattern mask 2, the greater the number of disparity values which can be encoded and the better the ECC protection (e.g., for 3-D imaging system 100 or other system which utilizes a coded word 7 produced using the disclosed techniques). However, as will be further appreciated, this also may increase the minimum detectable object (e.g., the smallest object that the imaging input device 3 can detect).

FIG. 4 is a flow diagram illustrating a process for generating a coded word 7 for patterning a mask 2 for use in generating structured light, in accordance with an embodiment of the present disclosure. As can be seen, a 9-bit disparity word 13 is first converted to 10-bit data word 11, for example, using an 8-bit/10-bit converter 14. Thereafter, the ECC bits 12 (e.g., one or more checksum bits) are added thereto, for example, using ECC mechanism 15, thereby producing a 15-bit coded word 7. As previously noted, and in accordance with an embodiment, the 15-bit coded word 7 can be partitioned, for example, in a 3×5 matrix and used to pattern mask 2, which in turn can be utilized to provide structured light, for example, for system 100 or any other suitable 3-D imaging system, as will be apparent in light of this disclosure. Also, as previously noted, the ECC bits 12 can be, in some example embodiments, one of the Hamming codes. In an example case, ECC bits 12 may be a Hamming code including one checksum bit for the even bits, another checksum bit for those divided by 4, and another checksum bit for those divided by 8. Numerous variations will be apparent in light of this disclosure.

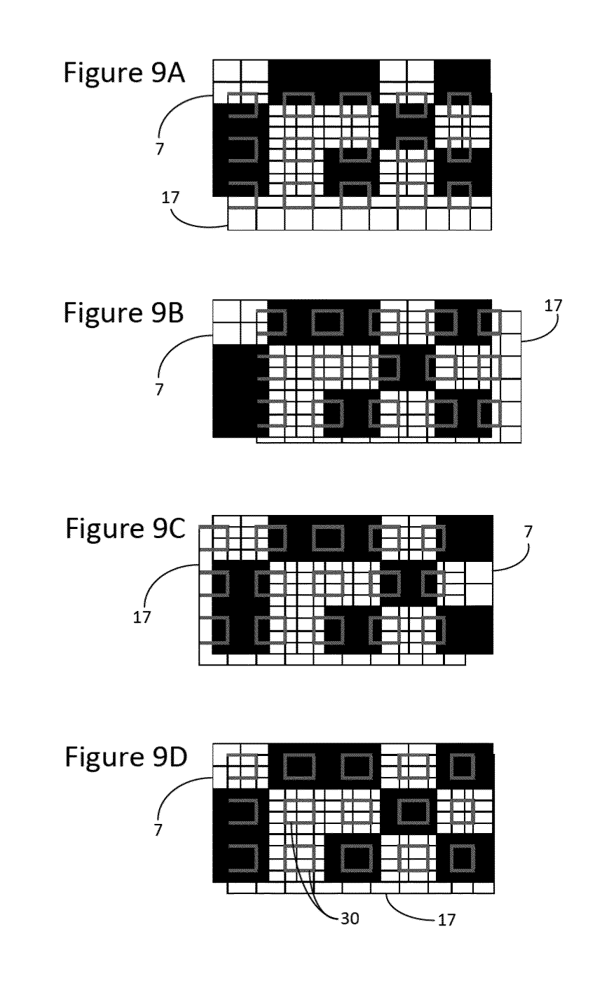

FIG. 5 demonstrates the alignment 18 of an example coded transmitter word 7 with respect to an example receiver matrix 17, in accordance with an embodiment of the present disclosure. As can be seen in this example instance, the receiver matrix 17 (e.g., the matrix of imaging input device 3) comprises a 6×10 arrangement of pixels (60 pixels total), and four pixels of the receiver matrix 17 cover one bit of the transmitter word 7 (e.g., here, a 15-bit transmitter word 7), providing transmitted pattern 18. In accordance with an embodiment, this may help to ensure that even when not properly aligned, at least one pixel of imaging input device 3 is fully covered, and the correct high and low lighting levels can be accurately measured, as will be explained below, for instance, with reference to FIG. 9A-9D.

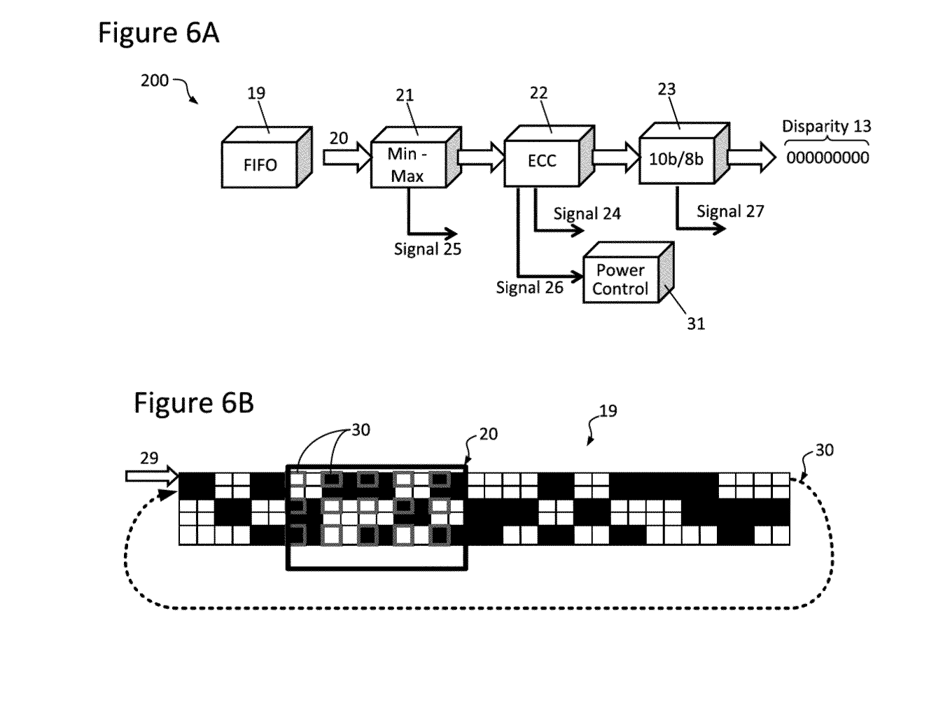

FIG. 6A is a block diagram of a receiver 200 configured in accordance with an embodiment of the present disclosure. As can be seen, receiver 200 includes: a first-in/first-out (FIFO) module 19; a minimum-maximum level detection module 21 configured to output a control signal 25; an ECC mechanism module 22 configured to output control signals 24 and 26, the latter of which may be directed to a light source control module 31 operatively coupled therewith; and a 10-bit/8-bit encoder module 23 configured to output a control signal 27. A discussion of each of these occurs below. As can further be seen, the computational pipeline of receiver 200 outputs a disparity 13 (e.g., 8-bit disparity word with an additional disparity bit), which can be used, for example, as discussed above with reference to FIG. 4. In some cases, receiver 200 can be integrated or otherwise operatively coupled, for example, with imaging input device 3.

FIG. 6B illustrates a FIFO module 19 configured in accordance with an embodiment of the present disclosure. In the depicted example embodiment, FIFO module 19 is a 5-line pixel FIFO which can contain up to five lines of video data. It should be noted, however, that the present disclosure is not so limited, as in other embodiments, FIFO module 19 may have lesser (e.g., 4 lines or fewer) or greater (e.g., 6 lines or more) capacity for video data, as desired for a given target application or end-use. In any case, a moving window 20 may be transitioned along the data contents of FIFO module 19 and used to acquire data therefrom. For instance, as can be seen from FIG. 6B, moving window 20 can be configured, in an example embodiment, to acquire fitly gross pixels (five lines of ten pixels each) from the video data within FIFO module 19 and to select fifteen net pixels 30 therefrom. As will be appreciated in light of this disclosure moving window 20 is not limited to only fifty gross pixels or fifteen net pixels 30; other embodiments may have a moving window 20 configured to acquire a lesser or greater quantity of gross pixels and/or net pixels. In a more general sense, and in accordance with some embodiments, moving window 20 can be configured to acquire any amount of video data from FIFO module 19, as desired for a given target application or end-use.

As can further be seen from FIG. 6B, a new pixel value 29 is entered into the first line of FIFO module 19 at each clock cycle, the relevant quantity of net pixels (e.g., fifteen net pixels 30, as in FIG. 6B) are taken from moving window 20 and passed through the computational pipeline of receiver 200, and a new set of output signals 13, 24, 25, 26, and 27 is generated. The last bit from the first line of FIFO module 19 is then inserted as the first bit of the second line of FIFO module 19 (as generally indicated by the dotted arrow in FIG. 6B). In a similar fashion, the last bits of each of the second, third, and fourth lines of FIFO module 19 are inserted as the first bits of the third, fourth, and fifth lines, respectively, of FIFO module 19. FIFO modules 19 of greater or lesser capacity can adopt a similar approach, in other embodiments, as appropriate for a given target application or end-use.

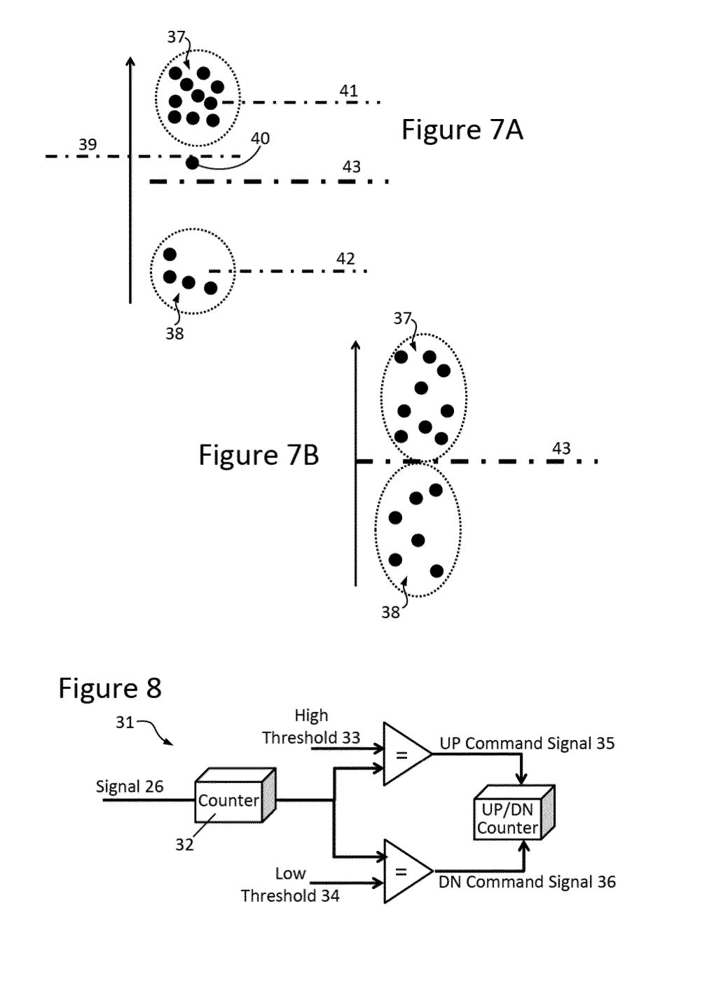

Returning to FIG. 6A, the data acquired by moving window 20 can be provided to minimum-maximum level detection module 21, in accordance with an embodiment. Although the 8-bit/10-bit converter 14 (e.g., discussed above with reference to FIG. 3) generally ensures a similar quantity of white and black pixels, there may be some misalignment in transmitted pattern 18 in some instances. For example, consider FIGS. 7A and 7B, which represent operation of minimum-maximum level detection module 21, in accordance with an embodiment of the present disclosure. In the depicted example case, eleven black pixels 37 and four white pixels 38 are present. The first average threshold 39 is calculated on all fifteen pixels, but misses a single pixel 40. Thereafter, calculation of the means of all pixels above (e.g., mean value 41) and below (e.g., mean value 42) the first average threshold 39 is performed. The average between mean 41 and mean 42 can be the final brightness threshold 43 used, for example, for pixel detection. The standard deviation of values above the eleven black pixels 37) and below (e.g., the four white pixels 38) this second threshold 43 may be compared to another sanity threshold to ensure that the values are approximately within the same range, thereby helping to maintain good margin between the zeros and ones. This can be used, in accordance with an embodiment, to distinguish between: (1) transient pixels as in FIGS. 9A, 9B, and 9C (discussed below) where the standard deviation will be high as in FIG. 7B (e.g., when the variance is above threshold 43, the values may not be distinctly zero and one); and (2) the case of FIG. 9D (also discussed below) where the black and white threshold is distinct and the standard deviation will be low. In any case, the results may be output by minimum-maximum level detection module 21, for example, as control signal 25 and may indicate whether good black-white threshold has been achieved, in accordance with an embodiment.

Returning to FIG. 6A, the data can be provided thereafter to an ECC module 22, in accordance with an embodiment. ECC module 22 can implement, for example, a Hamming code and/or any other suitable error-correcting code or mechanism, as will be apparent in light of this disclosure. Also, as previously noted, ECC module 22 can be configured to output a control signal 24, for example, which indicates whether the cyclic redundancy check (CRC) data is valid, in accordance with an embodiment. Furthermore, as previously noted. ECC module 22 can be configured to output a control signal 26, for example, which indicates that the correction mechanism provided by ECC module 22 was utilized (e.g., that an error in the video data was detected and corrected). In some cases, control signal 26 may indicate, for example, that exactly one error was detected and thus ECC was required. As previously noted, other embodiments may utilize additional ECC bits, which may allow for detection and correction of more than one error (e.g., two, three, four, or more errors), in some instances. In some cases, this may help to provide additional robustness of data.

As can further be seen from FIG. 6A, control signal 26 can be provided, in accordance with an embodiment, to a downstream light source power control module 31. FIG. 8 is a block diagram of a light source power control module 31 configured in accordance with an embodiment of the present disclosure. For each frame, the total number of pixel sets with valid CRC, for example, only after ECC correction (e.g., that is, frames with exactly one error) is counted by a counter 32 and compared to a high threshold 33 and a low threshold 34, each of which can be set as desired for a given target application or end-use. If the resultant value provided by counter 32 is too high (e.g., higher than high threshold 33), meaning that there is a sufficiently high quantity of correctable errors, then the power driver of the light source 1 (e.g., which may be a laser) may receive an UP-command signal 35 which increases the output power to improve the signal-to-noise (S/N) ratio. If instead the resultant value provided by counter 32 is too low (e.g., lower than low threshold 34), meaning that the signal is high and there is a sufficiently low quantity of errors (e.g., no errors or only a few errors), then the power driver of light source 1 may receive a DN-command signal 36 which decreases the output power. In some instances, any resultant increase in the number of errors can be corrected using the disclosed techniques, and thus may not affect for else may negligibly affect) the final depth picture quality.

Returning to FIG. 6A, the data can be provided thereafter to a 10-bit/8-bit encoder module 23. In accordance with an embodiment, 10-bit/8-bit encoding module 23 can implement any suitable 10-bit/8-bit encoding scheme, as will be apparent in light of this disclosure. Also, as previously noted, 10-bit/18-bit encoder module 23 can be configured to output a control signal 27, for example, which indicates whether illegal 8-bit/10-bit code is present. Furthermore, 10-bit/8-bit encoder module 23 can be configured to output disparity 13, as discussed above with reference to FIG. 4.

As previously noted, there may be some misalignment in transmitted pattern 18 in some cases. For instance, consider FIGS. 9A-9D, which illustrate four example cases of misaligned transmit 7 and receive 17 patterns. In accordance with some embodiments, three of the four example cases (e.g., FIGS. 9A, 9B, and 9C) may be rejected by receiver 200 as missing at least one of: (1) control signal 25 indicating good black-white threshold; (2) control signal 24 indicating CRC data valid; and/or (3) control signal 27 indicating illegal 8-bit/10-bit code. However, the fourth example case (e.g., FIG. 9D) should contain valid pixel data, in accordance with an embodiment.

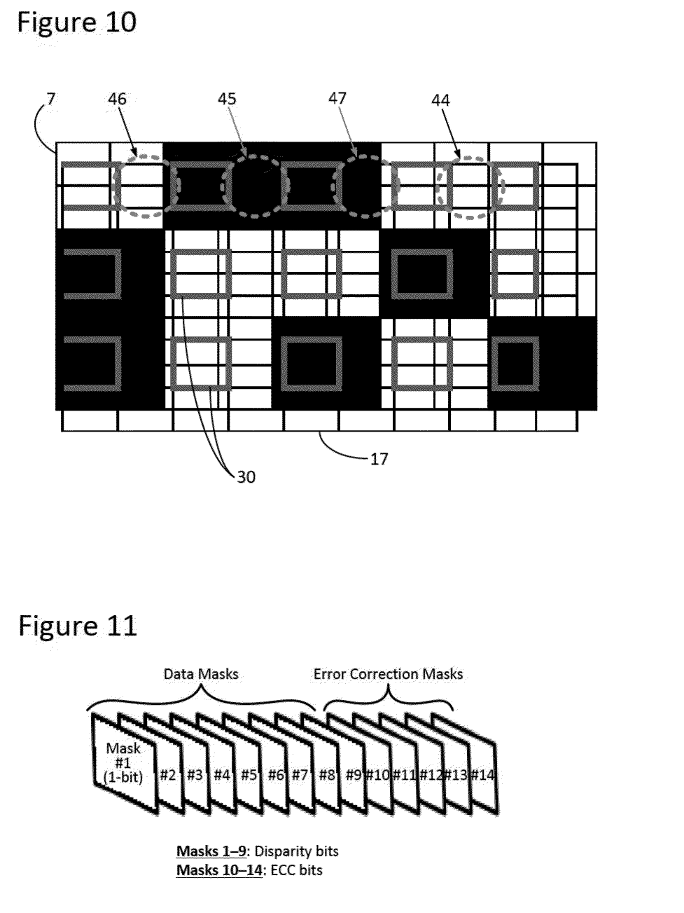

Once a valid set of pixels is detected, sub-pixel approximation can be performed on the transient pixels, in accordance with an embodiment. For example, consider FIG. 10, which represents an example implementation of a sub-pixel alignment mechanism, in accordance with an embodiment of the present disclosure. As can be seen, the sub-pixel approximation mechanism can be executed, for example, on the transient pixels between detected valid pixels 30, as generally denoted in FIG. 10 by the dotted ellipses 44, 45, 46, and 47 therein. In accordance with an embodiment, these transient pixels can be categorized, for example, as follows: (1) the scenario in which the pixel before and the pixel after the transient pixel are both white (e.g., as in ellipse 44); (2) the scenario in which the pixel before and the pixel after the transient pixel are both black (e.g., as in ellipse 45); (3) the scenario in which the transient pixel transitions from white to black (e.g., as in ellipse 46); and (4) the scenario in which the transient pixel transitions from black to white (e.g., as in ellipse 47). In the third described scenario (e.g., transition from white to black, as in ellipse 46), the higher the displacement, the higher the pixel value as more white is present, and thus it may be desirable to add those picture values (e.g., add one value by adding the value) to the sum, in accordance with an embodiment. Conversely, in the fourth described scenario (e.g., transition from black to white, as in ellipse 47), the higher the displacement, the lower the pixel value as more black is present, and thus it may be desirable to deduct those picture values (e.g., add the complement to 1) from the sum, in accordance with an embodiment. As will be appreciated in fight of this disclosure, the aforementioned sum defines the sub-pixel misalignment (e.g., when a pixel is partially 0 or partially 1). If the pixel is completely white, then the sum will be 1. If instead the pixel is completely black, then the sum will be 0. If the pixel is between those bounds, then the sum be fractional accordingly (e.g., if the pixel is in the middle, then the sum will be about 50% or ½). In any case, and in accordance with some embodiments averaging all values divided by the high minus low ratio provides the sub-pixel value.

Temporal Coded Light

FIG. 11 illustrates a plurality of masks for use in generating temporal structured light, in accordance with an embodiment of the present disclosure. As can be seen, the techniques provided herein also can be used to provide temporal coded light by adding additional slides or masks with ECC patterns. Such an embodiment can be used, for example, to improve the picture quality.

In this example embodiment, the mask patterned with a coded word is implemented with fourteen masks, each pixel representing one bit (1-bit) of the coded word. As can be further seen, the coded word includes nine disparity bits and five ECC bits, so as to provide a total of fourteen masks. As previously explained, the coded word further may include an encoding bit (e.g., one 8-bit/10-bit encoding bit) to help ensure the presence of a transient pixel in the data for black and white thresholds level detection.

A sub-set of the masks (masks 1-9) are each patterned with a single bit of the data portion of the coded word and are configured to transmit temporal coded light. Another sub-set of the masks (masks 10-14) are each patterned with a single bit of the error correction portion of the coded word and are configured to provide an ECC directed to the coded word provided by the plurality of masks (specifically, masks 1-9). Thus, in this example case, the coded word includes nine bits of disparity and an additional five bits of ECC for a total of fourteen bits, and fourteen corresponding masks are provided to transmit those bits. The transmission of these bits is spaced in time, such that each bit is transmitted separately from other bits using its corresponding mask. The ECC mechanism can be implemented as previously described herein, taking the fourteen bits and generating a corrected nine bits of disparity.

Numerous other variations of providing temporal coded light will be apparent in light of this disclosure. For instance, in other embodiments, a subset of coded word bits can be provided on the masks, such that each mask is configured to transmit one or more bits of the coded word. Different masks may transmit a different number of bits, and they need not be limited to one bit per mask.

### Example System

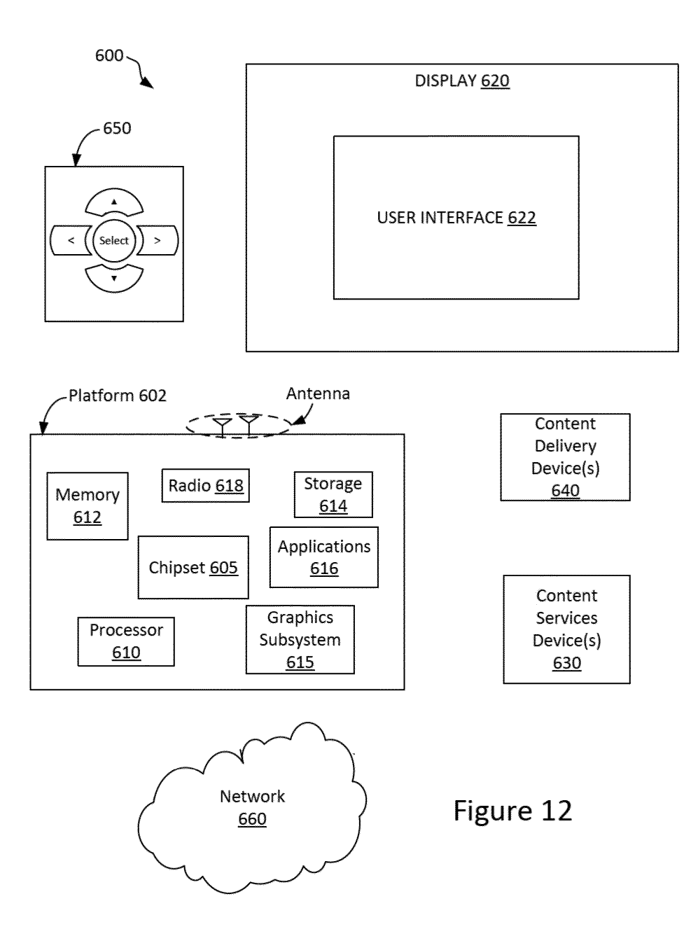

FIG. 12 illustrates an example system 600 that may carry out the techniques for providing structured light encoded with a coded word including error-correcting code (ECC) to detect and correct errors as described herein, in accordance with some embodiments. In some embodiments, system 600 may be a media system, although system 600 is not limited to this context. For example, system 600 may be incorporated into a personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, set-top box, game console, or other such computing environments capable of performing graphics rendering operations.

In some embodiments, system 600 comprises a platform 602 coupled to a display 620. Platform 602 may receive content from a content device such as content services device(s) 630 or content delivery device(s) 640 or other similar content sources. A navigation controller 650 comprising one or more navigation features may be used to interact, for example, with platform 602 and/or display 620. Each of these example components is described in more detail below. In some embodiments, platform 602 may comprise any combination of a chipset 605, processor 610, memory 612, storage 614, graphics subsystem 615, applications 616, and/or radio 618. Chipset 605 may provide intercommunication among processor 610, memory 612, storage 614, graphics subsystem 615, applications 616, and/or radio 618. For example, chipset 605 may include a storage adapter (not depicted) capable of providing intercommunication with storage 614.

Processor 610 may be implemented, for example, as Complex Instruction Set Computer (CISC) or Reduced Instruction Set Computer (RISC) processors, x86 instruction set compatible processors, multi-core, or any other microprocessor or central processing unit (CPU). In some embodiments, processor 610 may comprise dual-core processor(s), dual-core mobile processor(s), and so forth. Memory 612 may be implemented, for instance, as a volatile memory device such as, but not limited to, a Random Access Memory (RAM), Dynamic Random Access Memory (DRAM), or Static. RAM (SRAM). Storage 614 may be implemented, for example, as a non-volatile storage device such as, but not limited to, a magnetic disk drive, optical disk drive, tape drive, an internal storage device, an attached storage device, flash memory, battery backed-up SDRAM (synchronous DRAM), and/or a network accessible storage device. In some embodiments, storage 614 may comprise technology to increase the storage performance enhanced protection for valuable digital media when multiple hard drives are included, for example.

Graphics subsystem 615 may perform processing of images such as still or video for display. Graphics subsystem 615 may be a graphics processing unit (GPU) or a visual processing unit (VPU), for example. An analog or digital interface may be used to communicatively couple graphics subsystem 615 and display 620. For example, the interface may be any of a High-Definition Multimedia Interface (HDMI), DisplayPort, wireless HDMI, and/or wireless HD compliant techniques. Graphics subsystem 615 could be integrated into processor 610 or chipset 605. Graphics subsystem 615 could be as stand-alone card communicatively coupled to chipset 605. The techniques for providing structured light encoded with a coded word including error-correcting code (ECC) to detect and correct errors described herein may be implemented in various hardware architectures. For example, the techniques for providing structured light encoded with a coded word including error-correcting code (ECC) to detect and correct errors as provided herein may be integrated within a graphics and/or video chipset. Alternatively, a discrete security processor may be used. In still another embodiment, the graphics and/or video functions including the techniques for providing structured light encoded with a coded word including error-correcting code (ECC) to detect and correct errors may be implemented by a general purpose processor, including a multi-core processor.

Radio 618 may include one or more radios capable of transmitting and receiving signals using various suitable wireless communications techniques. Such techniques may involve communications across one or more wireless networks. Exemplary wireless networks may include, but are not limited to, wireless local area networks (WLANs), wireless personal area networks (WPANs), wireless metropolitan area network (WMANs), cellular networks, and satellite networks. In communicating across such networks, radio 618 may operate in accordance with one or more applicable standards in any version.

In some embodiments, display 620 may comprise any television or computer-type monitor or display. Display 620 may comprise, for example, a liquid crystal display (LCD) screen, electrophoretic display (EPD) or liquid paper display, flat panel display, touchscreen display, television-like device, and/or a television. Display 620 may be digital and/or analog. In some embodiments, display 620 may be a holographic or three-dimensional (3-D) display. Also, display 620 may be a transparent surface that may receive a visual projection. Such projections may convey various forms of information, images, and/or objects. For example, such projections may be a visual overlay for a mobile augmented reality (MAR) application. Under the control of one or more software applications 616, platform 602 may display a user interface 622 on display 620.

In some embodiments, content services device(s) 630 may be hosted by any national, international, and/or independent service and thus may be accessible to platform 602 via the Internet or other network, for example. Content services device(s) 630 may be coupled to platform 602 and/or to display 620. Platform 602 and/or content services device(s) 630 may be coupled to a network 660 to communicate (e.g., send and/or receive) media information to and from network 660. Content delivery device(s) 640 also may be coupled to platform 602 and/or to display 620. In some embodiments, content services device(s) 630 may comprise a cable television box, personal computer (PC), network, telephone. Internet-enabled devices or appliance capable of delivering digital information and/or content, and any other similar device capable of unidirectionally or bi-directionally communicating content between content providers and platform 602 and/or display 620, via network 660 or directly. It will be appreciated that the content may be communicated unidirectionally and/or bi-directionally to and from any one of the components in system 600 and a content provider via network 660. Examples of content may include any media information including, for example, video, music, graphics, text, medical and gaming content, and so forth.

Content services device(s) 630 receives content such as cable television programming including media information, digital information, and/or other content. Examples of content providers may include any cable or satellite television or radio or Internet content providers. The provided examples are not meant to limit the present disclosure. In some embodiments, platform 602 may receive control signals from navigation controller 650 having one or more navigation features. The navigation features of controller 650 may be used to interact with user interface 622, for example. In some embodiments, navigation controller 650 may be a pointing device that may be a computer hardware component (specifically human interface device) that allows a user to input spatial (e.g., continuous and multi-dimensional) data into a computer. Many systems such as graphical user interfaces (GUI) and televisions and monitors allow the user to control and provide data to the computer or television using physical gestures.

Movements of the navigation features of controller 650 may be echoed on a display e.g., display 620) by movements of a pointer, cursor, focus ring, or other visual indicators displayed on the display. For example, under the control of software applications 716, the navigation features located on navigation controller 650 may be mapped to virtual navigation features displayed on user interface 622, for example. In some embodiments, controller 650 may not be a separate component but integrated into platform 602 and/or display 620. Embodiments however, are not limited to the elements or in the context shown or described herein, as will be appreciated.

In some embodiments, drivers (not shown) may comprise technology to enable users to instantly turn on and off platform 602 like a television with the touch of a button after initial boot-up, when enabled, for example. Program logic may allow platform 602 to stream content to media adaptors or other content services device(s) 630 or content delivery device(s) 640 when the platform is turned “off”. In addition, chip set 605 may comprise hardware and/or software support for 5.1 surround sound audio and/or high definition 7.1 surround sound audio, for example. Drivers may include a graphics driver for integrated graphics platforms. In some embodiments, the graphics driver may comprise a peripheral component interconnect (PCI) express graphics card.

In various embodiments, any one or more of the components shown in system 600 may be integrated. For example, platform 602 and content services device(s) 630 may be integrated, or platform 602 and content delivery device(s) 640 may be integrated, or platform 602, content services device(s) 630, and content delivery device(s) 640 may be integrated, for example. In various embodiments, platform 602 and display 620 may be an integrated unit. Display 620 and content service device(s) 630 may be integrated, or display 620 and content delivery device(s) 640 may be integrated, for example. These examples are not meant to limit the present disclosure.

In various embodiments, system 600 may be implemented as a wireless system, a wired system, or a combination of both. When implemented as a wireless system, system 600 may include components and interfaces suitable for communicating over a wireless shared media, such as one or more antennas, transmitters, receivers, transceivers, amplifiers, filters, control logic, and so forth. An example of wireless shared media may include portions of a wireless spectrum, such as the radio frequency (RF) spectrum and so forth. When implemented as a wired system, system 600 may include components and interfaces suitable for communicating over wired communications media, such as input/output (I/O) adapters, physical connectors to connect the I/O adapter with a corresponding wired communications medium, a network interface card (NIC), disc controller, video controller, audio controller, and so forth. Examples of wired communications media may include a wire, cable, metal leads, printed circuit board (PCB), backplane, switch fabric, semiconductor material, twisted-pair wire, co-axial cable, fiber optics, and so forth.

Platform 602 may establish one or more logical or physical channels to communicate information. The information may include media information and control information. Media information may refer to any data representing content meant for a user. Examples of content may include, for example, data from a voice conversation, videoconference, streaming video, email or text messages, voice mail message, alphanumeric symbols, graphics, image, video, text and so forth. Control information may refer to any data representing commands, instructions, or control words meant for an automated system. For example, control information may be used to route media information through a system or instruct a node to process the media information in a predetermined manner (e.g., using the techniques for providing structured light encoded with a coded word including error-correcting code (ECC) to detect and correct errors as described herein). The embodiments, however, are not limited to the elements or context shown or described in FIG. 12.

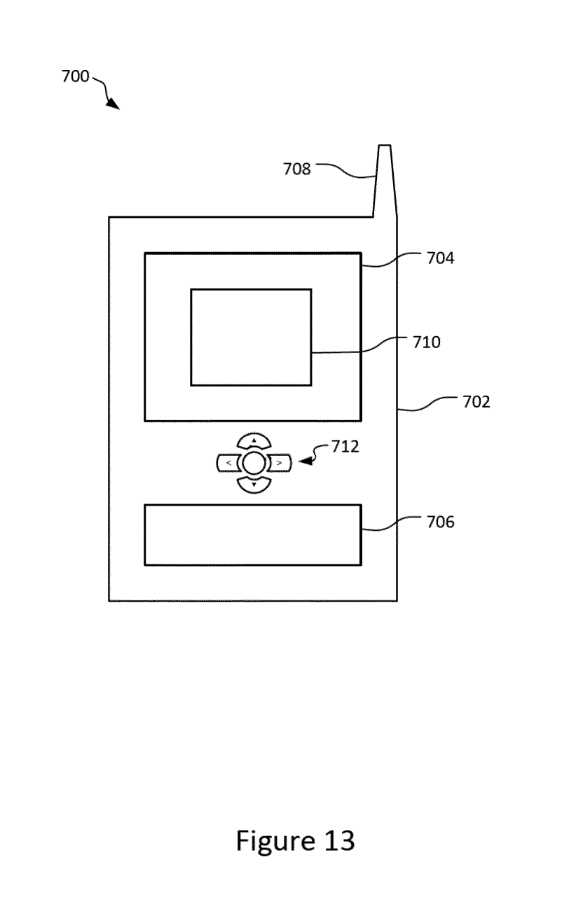

As described above, system 600 may be embodied in varying physical styles or form factors. FIG. 13 illustrates embodiments of a small form factor device 700 in which system 600 may be embodied. In some embodiments, for example, device 700 may be implemented as a mobile computing device having wireless capabilities. A mobile computing device may refer to any device having a processing system and a mobile power source or supply, such as one or more batteries, for example.

As previously described, examples of a mobile computing device may include a personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, and so forth.

Examples of a mobile computing device also may include computers that are arranged to be worn by a person, such as a wrist computer, finger computer, ring computer, eyeglass computer, belt-clip computer, arm-band computer, shoe computers, clothing computers, and other wearable computers. In some embodiments, for example, a mobile computing device may be implemented as a smart phone capable of executing computer applications, as well as voice communications and/or data communications. Although some embodiments may be described with a mobile computing device implemented as a smart phone by way of example, it may be appreciated that other embodiments may be implemented using other wireless mobile computing devices as well. The embodiments are not limited in this context.

As shown in FIG. 13, device 700 may comprise a housing 702, a display 704, an input/output (I/O) device 706, and an antenna 708. Device 700 also may comprise navigation features 712. Display 704 may comprise any suitable display unit for displaying information appropriate for a mobile computing device. I/O device 706 may comprise any suitable I/O device for entering information into a mobile computing device. Examples for I/O device 706 may include an alphanumeric keyboard, a numeric keypad, a touch pad, input keys, buttons, switches, rocker switches, microphones, speakers, voice recognition device and software, and so forth. Information also may be entered into device 700 by way of microphone. Such information may be digitized by a voice recognition device. The embodiments are not limited in this context.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits (IC), application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Whether hardware elements and/or software elements are used may vary from one embodiment to the next in accordance with any number of factors, such as desired computational rate, power levels, heat tolerances, processing cycle budget, input data rates, output data rates, memory resources, data bus speeds, and other design or performance constraints.

Some embodiments may be implemented, for example, using a machine-readable medium or article which may store an instruction or a set of instructions that, if executed by a machine, may cause the machine to perform a method and/or operations in accordance with an embodiment. Such a machine may include, for example, any suitable processing platform, computing platform, computing device, processing device, computing system, processing system, computer, processor, or the like, and may be implemented using any suitable combination of hardware and software. The machine-readable medium or article May include, for example, any suitable type of memory unit, memory device, memory article, memory medium, storage device, storage article, storage medium and/or storage unit, for example, memory, removable or non-removable media, erasable or non-erasable media, writeable or re-writ able media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of executable code implemented using any suitable high-level, low-level, object-oriented, visual, compiled, and/or interpreted programming language.

Unless specifically stated otherwise, it may be appreciated that terms such as “processing.” “computing.” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers, or other such information storage, transmission, or displays. The embodiments are not limited in this context.

### Further Example Embodiments

The following examples pertain to further embodiments, from which numerous permutations and configurations will be apparent.

Example 1 is an imaging system comprising: a light source; a mask patterned with a coded word which includes an error-correcting code (ECC), wherein the patterned mask is configured to transmit light emitted by the light source as structured light encoded with the coded word; and an imaging input device which is configured to receive the structured light.

Example 2 includes the subject matter of any of Examples 1 and 3-16, wherein the coded word is configured to correct one data error and to detect two data errors.

Example 3 includes the subject matter of any of Examples 1-2 and 4-16, wherein the coded word is configured to detect a quantity of data errors, and an output power of the light source is at least one of increased and/or decreased based on that quantity of detected data errors.

Example 4 includes the subject matter of any of Examples 1-3 and 5-16, wherein the coded word comprises a plurality of data bits and ECC bits.

Example 5 includes the subject matter of any of Examples 4 and 6-7, wherein the plurality of data bits comprises a disparity code.

Example 6 includes the subject matter of Example 5 further including one 8-bit/10-bit encoding hit to provide at least one transient pixel for black and white intensity level detection.

Example 7 includes the subject matter of any of Examples 1-6 and 8-16, wherein the coded word comprises a 10-bit representation of 8-bit disparity and five ECC bits.

Example 8 includes the subject matter of any of Examples 1-7 and 9-16, wherein the coded word is provided in at least one of a 3×5 matrix, a 4×4 matrix, a 4×5 matrix, and/or a 5×5 matrix.

Example 9 includes the subject matter of any of Examples 1-8 and 10-16, wherein the coded word includes nine data bits comprising a disparity code, five ECC bits comprising a Hamming code, and one 8-bit/10-bit encoding bit.

Example 10 includes the subject matter of any of Examples 1-9 and 11-16, wherein the imaging input device comprises a still camera or a video camera.

Example 11 includes the subject matter of any of Examples 1-10 and 12-16, wherein the imaging input device comprises at least one of an optics assembly, an image sensor, and/or an image/video encoder.

Example 12 includes the subject matter of any of Examples 1-11 and 13-16, wherein the system further includes a processing unit operatively coupled with the imaging input device and configured to process imaging data captured thereby.

Example 13 includes the subject matter of Example 12, wherein the processing unit is configured to extract three-dimensional (3-D) surface shape of an object illuminated by the structured light.

Example 14 includes the subject matter of any of Examples 1-13 and 15-16, wherein the patterned mask comprises a plurality of masks, each mask pixel patterned with a single bit of the coded word, one sub-set of the plurality of masks being configured to transmit temporal coded light and another sub-set of the plurality of masks being patterned with ECC bits.

Example 15 is a computing device which includes the imaging system of any of Examples 1-14 and 16.

Example 16 includes the subject matter of Example 15, wherein the computing device comprises at least one of a laptop/notebook computer, a tablet computer, a mobile phone, a smartphone, a personal digital assistant (PDA), a cellular handset, a handheld gaming device, a gaming platform, a desktop computer, a smart television, and/or a videoconferencing system.

Example 17 is a method of three-dimensional (3-D) imaging, the method comprising: illuminating an Object with structured light encoded with a coded word including an error-correcting code (ECC); capturing structured light which is reflected from the object; and comparing the reflected structured light with the original structured light to extract a 3-D surface shape of the object illuminated by the structured light.

Example 18 includes the subject matter of any of Examples 17 and 19-31, wherein the coded word is configured to correct one data error and to detect two data errors.

Example 19 includes the subject matter of any of Examples 17-18 and 20-31, wherein the coded word comprises a plurality of data bits and ECC bits.

Example 20 includes the subject matter of any of Examples 19 and 21-22, wherein the plurality of data bits comprises a disparity code.

Example 21 includes the subject matter of Example 20 further including one 8-bit/10-bit encoding bit to provide at least one transient pixel for black and White intensity level detection.

Example 22 includes the subject matter of any of Examples 17-21 and 23-31, wherein the coded word comprises a 10-bit representation of 8-bit disparity and five ECC bits.

Example 23 includes the subject matter of any of Examples 17-22 and 24-31, wherein the coded word is provided in at least one of a 3×5 matrix, a 4×4 matrix, a 4×5 matrix, and/or a 5×5 matrix.

Example 24 includes the subject matter of any of Example 17-23 and 25-31, wherein the coded word includes nine data bits comprising a disparity code, five ECC bits comprising a Hamming code, and one 8-bit/10-bit encoding bit.

Example 25 includes the subject matter of any of Examples 17-24 and 26-31, wherein illuminating the object with structured light is performed using a light source and a mask patterned with the coded word, and wherein the patterned mask is configured to transmit light emitted by the light source as structured light encoded with the coded word.

Example 26 includes the subject matter of Example 25, wherein the light source comprises a laser.

Example 27 includes the subject matter of Example 25, wherein the coded word is configured to detect a quantity of data errors, and an output power of the light source is at least one of increased and/or decreased based on that quantity of detected data errors.

Example 28 includes the subject matter of any of Examples 17-27 and 29-31, wherein illuminating the object with structured light is performed using a light source and a plurality of masks, each mask pixel patterned with a single bit of the coded word, one sub-set of the plurality of masks being configured to transmit temporal coded light and another sub-set of the plurality of masks being patterned with ECC bits.

Example 29 includes the subject matter of any of Examples 17-28 and 30-31, wherein capturing the reflected structured light is performed using a still camera or to video camera.

Example 30 includes the subject matter of any of Examples 17-29 and 31, wherein extraction of 3-D surface shape of the object illuminated by the structured light is performed using triangulation.

Example 31 is a computer-readable medium encoded with instructions that, when executed by one or more processors, causes a process for three-dimensional (3-D) imaging to be carried out, the process including the method of any of Examples 17-30.

Example 32 is a structured-light system comprising, a transmitter comprising: a light source; and a mask patterned with a coded word which includes an error-correcting code (ECC), wherein the patterned mask is configured to transmit light emitted by the light source as structured light encoded with the coded word; and a receiver comprising; a first-in/first-out (FIFO) module configured to contain imaging data; a level detection module communicatively coupled with the FIFO module; an ECC module communicatively coupled with the level detection module; and a 10-bit/8-bit encoder module communicatively coupled with the ECC module; wherein the receiver is configured to output disparity code that is used in generating the coded word.

Example 33 includes the subject matter of any of Examples 32 and 34-51, wherein the coded word is configured to correct one data error and to detect two data errors.

Example 34 includes the subject matter of any of Examples 32-33 and 35-51, wherein the coded word is configured to detect a quantity of data errors, and an output power of the light source is at least one of increased and/or decreased based on that quantity of detected data errors.

Example 35 includes the subject matter of any of Examples 32-34 and 36-51, wherein the coded word comprises a plurality of data bits and ECC bits.

Example 36 includes the subject matter of Example 35, wherein the plurality of data bits comprises the disparity code which the receiver is configured to output.

Example 37 includes the subject matter of Example 36 further including one 8-bit/10-bit encoding bit to provide at least one transient pixel for black and white intensity level detection by the level detection module.

Example 38 includes the subject matter of any of Examples 32-37 and 39-51, wherein the FIFO module is configured to contain five lines of imaging data.

Example 39 includes the subject matter of any of Examples 32-38 and 40-51, wherein the FIFO module is configured to have a plurality of pixels from the imaging data acquired by a moving window.

Example 40 includes the subject matter of Example 39, wherein the moving window acquires fitly gross pixels from the imaging data.

Example 41 includes the subject matter of Example 39, wherein the moving window acquires fifteen net pixels from the imaging data.

Example 42 includes the subject matter of any of Examples 32-41 and 43-51, wherein the level detection module is configured to: calculate a first average threshold based on pixels acquired from the imaging data of the FIFO module; calculate a first mean value of pixels above the first average threshold; calculate a second mean value of pixels below the first average threshold; and calculate a second average threshold based on the first and second mean values.

Example 43 includes the subject matter of Example 42, wherein the second average threshold is used as a brightness threshold for pixel detection.

Example 44 includes the subject matter of Example 42, wherein a standard deviation of pixels above and pixels below the second average threshold is used to distinguish steady pixels from transient pixels.

Example 45 includes the subject matter of Example 44, wherein the level detection module is further configured to perform a sub-pixel approximation for transient pixels, wherein the sub-pixel approximation is used in pixel alignment between the transmitter and the receiver.

Example 46 includes the subject matter of any of Examples 32-45 and 47-51, wherein the level detection module is configured to output a signal indicating, black-white threshold.

Example 47 includes the subject matter of any of Examples 32-46 and 48-51, wherein the ECC module is configured to output a signal indicating that cyclic redundancy check (CRC) data is valid.

Example 48 includes the subject matter of any of Examples 32-47 and 49-51, wherein the ECC module is configured to output a signal indicating that error correction occurred.

Example 49 includes the subject matter of any of Examples 32-48 and 50-51, wherein the 10-bit/8-bit encoder module is configured to output a signal indicating existence of illegal 8-bit/10-bit code.

Example 50 includes the subject matter of any of Examples 32-49 and 51, wherein the structured-light system further includes a control module operatively coupled with the light source and the ECC module, wherein the control module is configured to control an output power of the light source.

Example 51 includes the subject matter of Example 50, wherein the control module includes a counter which counts a quantity of instances in which error correction by the ECC module occurred, and wherein the output power of the light source is at least one of increased and/or decreased by the control module based on that quantity of error correction instances.

Example 52 includes the subject matter of any of Examples 32-51, wherein the patterned mask comprises a plurality of masks, each mask pixel patterned with a single bit of the coded word, one sub-set of the plurality of masks being configured to transmit temporal coded light and another sub-set of the plurality of masks being patterned with ECC bits.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future-filed applications claiming priority to this application may claim the disclosed subject matter in a different manner and generally may include any set of one or more limitations as variously disclosed or otherwise demonstrated herein.

1. An imaging system comprising:
a light source;
a mask patterned with a coded word which includes an error-correcting code (ECC), wherein the patterned mask is configured to transmit light emitted by the light source as structured light encoded with the coded word; and
an imaging input device which is configured to receive the structured light.

2. The system of claim 1, wherein the coded word is configured to correct one data error and to detect two data errors.

3. The system of claim 1, wherein the coded word is configured to detect a quantity of data errors, and wherein an output power of the light source is at least one of increased and/or decreased based on that quantity of detected data errors.

4. The system of claim 1, wherein the coded word comprises a plurality of data bits and ECC bits.

5. The system of claim 4, wherein the plurality of data bits comprises a disparity code.

6. The system of claim 5 further comprising one 8-bit/10-bit encoding bit to provide at least one transient pixel for black and white intensity level detection.

7. The system of claim 1, wherein the coded word comprises a 10-bit representation of 8-bit disparity and five ECC bits.

8. The system of claim 1, wherein the coded word is provided in at least one of a 3×5 matrix, a 4×4 matrix, a 4×5 matrix, and/or a 5×5 matrix.

9. The system of claim 1, wherein the coded word includes nine data bits comprising a disparity code, five ECC bits comprising a Hamming code, and one 8-bit/10-bit encoding bit.

10. The system of claim 1, wherein the patterned mask comprises a plurality of masks, each mask pixel patterned with a single bit of the coded word, one sub-set of the plurality of masks being configured to transmit temporal coded light and another sub-set of the plurality of masks being patterned with ECC bits.

11. A computing device comprising the imaging system of claim 1, the computing device comprising at least one of a laptop/notebook computer, a tablet computer, a mobile phone, a smartphone, a personal digital assistant (PDA), a cellular handset, a handheld gaming device, a gaming platform, a desktop computer, a smart television, and/or a videoconferencing system.

12. A computer-readable medium encoded with instructions that, when executed by one or more processors, causes a process for three-dimensional (3-D) imaging to be carried out, the process comprising:
illuminating an object with structured light encoded with a coded word including an error-correcting code (ECC);
capturing structured light which is reflected from the object; and
comparing the reflected structured light with the original structured light to extract a 3-D surface shape of the object illuminated by the structured light.

13. The computer-readable medium of claim 12, wherein the coded word is configured to correct one data error and to detect two data errors.

14. The computer-readable medium of claim 12, wherein the coded word comprises a plurality of data bits and ECC bits.

15. The computer-readable medium of claim 14, wherein the plurality of data bits comprises a disparity code.

16. The computer-readable medium of claim 15 further comprising one 8-bit/10-bit encoding bit to provide at least one transient pixel for black and white intensity level detection.

17. The computer-readable medium of claim 12, wherein the coded word comprises a 10-bit representation of 8-bit disparity and five ECC bits, and wherein the coded word is provided in at least one of a 3×5 matrix, a 4×4 matrix, a 4×5 matrix, and/or a 5×5 matrix.

18. The computer-readable medium of claim 12, wherein illuminating the object with structured light is performed using a light source and a mask patterned with the coded word, wherein the patterned mask is configured to transmit light emitted by the light source as structured light encoded with the coded word.

19. The computer-readable medium of claim 18, wherein the coded word is configured to detect a quantity of data errors, and wherein an output power of the light source is at least one of increased and/or decreased based on that quantity of detected data errors.

20. The computer-readable medium of claim 12, wherein illuminating the object with structured light is performed using a light source and a plurality of masks, each mask pixel patterned with a single bit of the coded word, one sub-set of the plurality of masks being configured to transmit temporal coded light and another sub-set of the plurality of masks being patterned with ECC bits, wherein the coded word is configured to detect a quantity of data errors, and wherein an output power of the light source is at least one of increased and/or decreased based on that quantity of detected data errors.

21. A structured-light system comprising:
a transmitter comprising:
a light source; and
a mask patterned with a coded word which includes an error-correcting code (ECC), wherein the patterned mask is configured to transmit light emitted by the light source as structured light encoded with the coded word; and
a receiver comprising:
a first-in/first-out (FIFO) module configured to contain imaging data;
a level detection module communicatively coupled with the FIFO module;
an ECC module communicatively coupled with the level detection module; and
a 10-bit/8-bit encoder module communicatively coupled with the ECC module;
wherein the receiver is configured to output a disparity code that is used in generating the coded word.

22. The system of claim 21, wherein the coded word is configured to detect a quantity of data errors, and wherein an output power of the light source is at least one of increased and/or decreased based on that quantity of detected data errors.

23. The system of claim 21, wherein the level detection module is configured to:
calculate a first average threshold based on pixels acquired from the imaging data of the FIFO module;
calculate a first mean value of pixels above the first average threshold;
calculate a second mean value of pixels below the first average threshold; and
calculate a second average threshold based on the first and second mean values, wherein the second average threshold is used as a brightness threshold for pixel detection, and wherein a standard deviation of pixels above and pixels below the second average threshold is used to distinguish steady pixels from transient pixels.

24. The system of claim 23, wherein the level detection module is further configured to perform a sub-pixel approximation for transient pixels, wherein the sub-pixel approximation is used in pixel alignment between the transmitter and the receiver.

25. The system of claim 21 further comprising a control module operatively coupled with the light source and the ECC module, wherein the control module includes a counter which counts a quantity of instances in which error correction by the ECC module occurred, and wherein the control module is configured to at least one of increase and/or decrease an output power of the light source based on that quantity of error correction instances.
